(19) United States
(12) Patent Application Publication
(10) Pub. No.: US 2015/0322571 A1
(43) Pub. Date: Nov. 12, 2015

(54) SUBSTRATE PROCESSING APPARATUS

(71) Applicant: Tokyo Electron Limited, Tokyo (JP)

(72) Inventors: Hideaki YAMASAKI, Nirasaki (JP); Takashi KAKEGAWA, Nirasaki (JP); Einosuke TSUDA, Nirasaki (JP); Tomohiro OOTA, Nirasaki (JP)

(21) Appl. No.: 14/705,508

(22) Filed: May 6, 2015

(30) Foreign Application Priority Data
May 7, 2014 (JP) 2014-096062

(51) Int. Cl. C23C 16/50; C23C 16/455; C23C 16/52; C23C 16/46

(52) U.S. Cl. CPC C23C 16/50; C23C 16/46; C23C 16/455; C23C 16/52

(57) ABSTRACT

A substrate processing apparatus for processing a substrate by using a plasma includes a processing chamber configured to airtightly accommodate a substrate, a lower electrode serving as a mounting table configured to mount thereon the substrate in the processing chamber, an upper electrode, serving as a shower plate having a plurality of gas supply openings, provided opposite to the substrate to be mounted on the mounting table, an insulating member disposed to surround an outer peripheral portion of the upper electrode, and a processing gas supply source configured to supply a processing gas into the processing chamber through the shower plate. The substrate processing apparatus further includes a heating unit provided at the insulating member to heat the insulating member.

### CROSS-REFERENCE TO RELATED APPLICATIONS

This application claims priority to Japanese Patent Application No. 2014-096062 filed on May 07, 2014, the entire contents of which are incorporated herein by reference.

### FIELD OF THE INVENTION

The disclosure relates to a substrate processing apparatus for processing a substrate by using a plasma of a predetermined processing gas.

### BACKGROUND OF THE INVENTION

Recently, there is employed a Ti film formed by plasma CVD (PECVD: Plasma Enhanced Chemical Vapor Deposition) as a material for use in ohmic contact for a source and a drain in semiconductor devices for 10 nm and 7 nm generations.

In order to form the Ti film by the plasma CVD, a wafer is mounted on a mounting table serving as a lower electrode provided in a depressurized processing chamber, and TiCl₄ gas is supplied as a processing gas to the wafer from a shower plate serving as an upper electrode. Further, a high frequency power is applied to the upper electrode. Accordingly, a plasma is generated in the processing chamber and the Ti film is formed on the wafer (see Japanese Patent Application Publication No. 2010-263126).

However, fine particles caused by a reaction by-product of the processing gas or by sputtering using a plasma generated in a processing chamber are adhered to an inner surface of the processing chamber. When the particles are adhered to the substrate, the yield of the product is decreased. Accordingly, in order to remove a particle source and prevent the adhesion of the particles to the wafer, film forming conditions in the processing chamber are optimized.

In addition, by heating the mounting table and the shower plate to a predetermined temperature to improve a quality of a film which is caused by the reaction by-product and adhered to the mounting table and the shower plate, peeling or crack of the film adhered to the mounting table and the shower plate is suppressed and thus the generation of particles is suppressed.

Recently, along with the trend toward miniaturization of semiconductor devices, it is required to suppress the generation of finer particles in order to ensure the yield. However, the known technique cannot sufficiently suppress the generation of particles of a required size and, thus, a new technique is needed.

### SUMMARY OF THE INVENTION

In view of the above, the disclosure provides a technique for suppressing generation of particles in a processing chamber in a substrate processing apparatus for processing a substrate by a plasma generated in the processing chamber.

In accordance with an aspect of the present invention, there is provided a substrate processing apparatus for processing a substrate by using a plasma, including: a processing chamber configured to airtightly accommodate a substrate; a lower electrode serving as a mounting table configured to mount thereon the substrate in the processing chamber; an upper electrode, serving as a shower plate having a plurality of gas supply openings, provided opposite to the substrate to be mounted on the mounting table; an insulating member disposed to surround an outer peripheral portion of the upper electrode; a processing gas supply source configured to supply a processing gas into the processing chamber through the shower plate; and a heating unit provided at the insulating member to heat the insulating member.

### BRIEF DESCRIPTION OF THE DRAWINGS

The objects and features of the disclosure will become apparent from the following description of embodiments, given in conjunction with the accompanying drawings, in which:

FIG. 1 is a vertical cross sectional view showing a schematic configuration of a substrate processing apparatus according to an embodiment;

FIG. 2 is a vertical cross sectional view showing a schematic configuration near an insulating member;

FIG. 3 is a top view showing a state where a heating unit is provided in a recess of the insulating member;

FIG. 4 is a vertical cross sectional view showing a schematic configuration near an insulating member according to another embodiment;

FIG. 5 is a view for explaining a state where an insulating layer and trenches are formed on a wafer;

FIG. 6 is a view for explaining a state where a Ti film is formed on the wafer;

FIG. 7 is a view for explaining a configuration near an upper electrode which is seen from the bottom side;

FIG. 8 is a vertical cross sectional view showing a state where a bottom surface of the insulating member is covered by a coating film;

FIG. 9 is a vertical cross sectional view showing a state where a metal plate for covering the bottom surface of the insulating member is provided; and

FIG. 10 is a vertical cross sectional view showing a schematic configuration near an upper electrode according to still another embodiment.

### DETAILED DESCRIPTION OF THE EMBODIMENTS

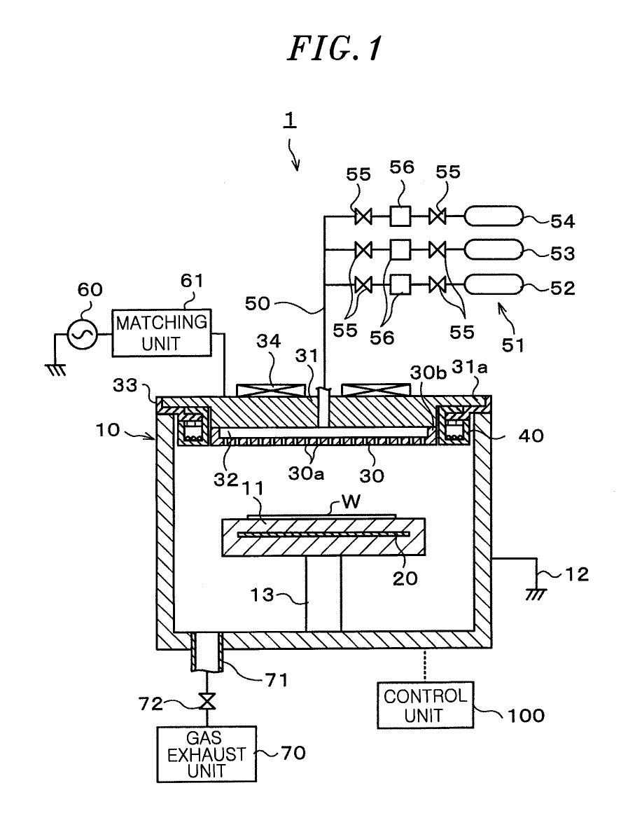

Hereinafter, embodiments will be described with reference to the accompanying drawings which form a part hereof. Throughout this specification and the drawings, like reference numerals will be used for like elements substantially having the same functions and redundant description thereof will be omitted. FIG. 1 is a vertical cross sectional view showing a schematic configuration of a substrate processing apparatus 1 according to an embodiment. In the present embodiment, the substrate processing apparatus 1 is a plasma processing apparatus for processing a substrate by using a plasma, and there will be described the case where a Ti film is formed on a wafer by using the substrate processing apparatus 1.

The substrate processing apparatus 1 includes: a substantially cylindrical processing chamber 10 having a closed bottom and an open top; and a mounting table 11, provided in the processing chamber 10, for mounting thereon a wafer W. The processing chamber 10 is electrically connected and grounded via a ground line 12. An inner wall of the processing chamber 10 is covered by a liner (not shown) having on a surface thereof a thermally sprayed film made of a plasma resistant material.

The mounting table 11 is made of a ceramic, e.g., aluminum nitride (AlN) or the like, and has on a surface thereof a coating film (not shown) made of a conductive material. A bottom surface of the mounting table 11 is supported by a supporting member 13 made of a conductive material and is electrically connected thereto. A lower end of the supporting member 13 is supported by the bottom surface of the processing chamber 10 and electrically connected thereto. Therefore, the mounting table 11 is grounded via the processing chamber 10 and serves as a lower electrode that forms a pair with an upper electrode to be described later. The structure of the lower electrode is not limited to that described in the present embodiment. For example, the lower electrode may be formed by burying a conductive member such as a metal mesh or the like in the mounting table 11.

An electric heater 20 is buried in the mounting table 11, so that the wafer W mounted on the mounting table 11 can be heated to a predetermined temperature. Provided at the mounting table 11 are a clamp ring (not shown) for fixing the wafer W onto the mounting table 11 by pressing the outer peripheral portion of the wafer W and elevating pins (not shown) for transferring the wafer W with respect to a transfer unit (not shown) provided at the outside of the processing chamber 10.

At an inner surface of the processing chamber 10, a substantially disc-shaped upper electrode 30 is provided above the mounting table 11 in parallel to the mounting table 11. In other words, the upper electrode 30 is disposed to face the wafer W mounted on the mounting table 11. The upper electrode 30 is made of a conductive metal, e.g., nickel (Ni) or the like.

A plurality of gas supply openings 30a is formed in the upper electrode 30 to penetrate through the upper electrode 30 in a thickness direction thereof. A protruding part 30b protruding upward is formed along the entire outer peripheral portion of the upper electrode 30. In other words, the upper electrode 30 has a substantially cylindrical shape having a closed bottom and an open top. The upper electrode 30 has a diameter smaller than an inner diameter of the processing chamber 10 so that the outer surface of the protruding part 30b is separated from the inner surface of the processing chamber 10 by a predetermined distance. Further, the upper electrode 30 has a diameter greater than the wafer W so that the surface of the upper electrode 30 which faces the mounting table 11 covers the entire surface of the wafer W mounted on the mounting table 11 when seen from the top, for example. A substantially disc-shaped lid 31 is disposed on the upper surface of the protruding part 30b. A space surrounded by the lid 31 and the upper electrode 30 serves as a gas diffusion space 32. As in the case of the upper electrode 30, the lid 31 is made of a conductive metal, e.g., nickel or the like. The lid 31 and the upper electrode 30 may be formed as one unit.

A locking part 31a is formed at an upper and outer peripheral portion of the lid 31 and protrudes radially outward. A bottom surface of the locking part 31a is held by a ring-shaped supporting member 33 supported at the upper portion of the processing chamber 10. The supporting member 33 is made of an insulating material, e.g., quartz or the like. Therefore, the upper electrode 30 and the processing chamber 10 are electrically insulated from each other. An electric heater 34 is provided on an upper surface of the lid 31. The lid 31 and the upper electrode 30 connected to the lid 31 can be heated to a predetermined temperature by the electric heater 34.

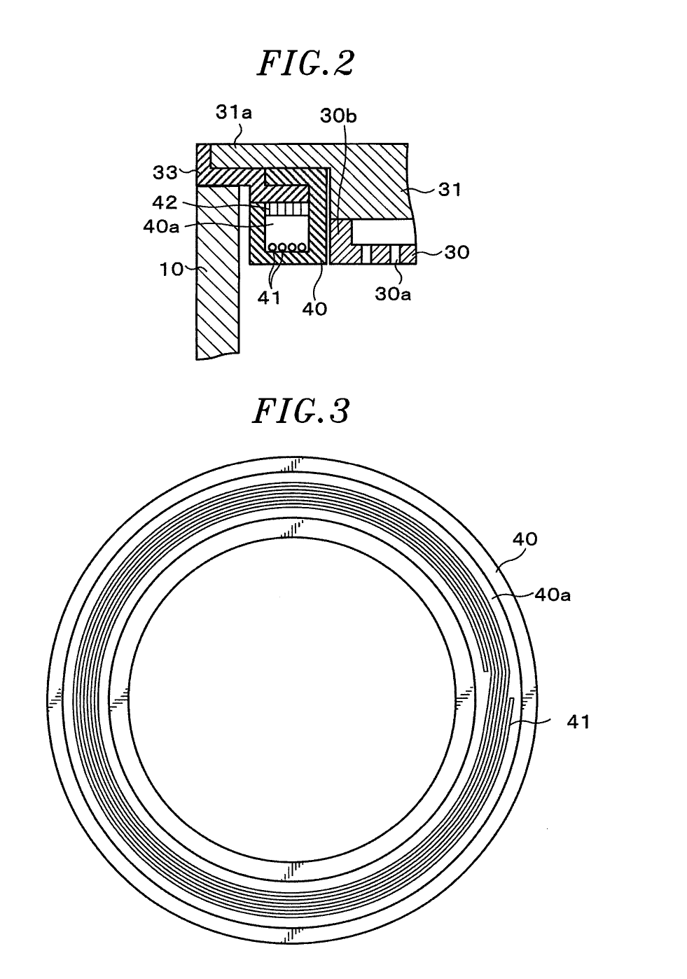

A ring-shaped insulating member 40 is provided at the outside of the protruding part 30b of the upper electrode 30 to surround the outer peripheral portion of the upper electrode 30. As shown in FIG. 2, a gap is formed between the upper electrode 30 and the insulating member 40. The insulating member 40 is made of, e.g., quartz. The bottom surface of the insulating member 40 is arranged to be flush with the bottom surface of the upper electrode 30 as shown in FIG. 2, so that the plasma is uniformly generated in the processing chamber 10 when a high frequency power is applied to the space between the lower electrode and the upper electrode 30. The insulating member 40 is supported by, e.g., the supporting member 33. An outer diameter of the insulating member 40 is smaller than the inner diameter of the processing chamber 10 so that a predetermined gap is formed between the outer surface of the insulating member 40 and the inner surface of the processing chamber 10 in a horizontal direction.

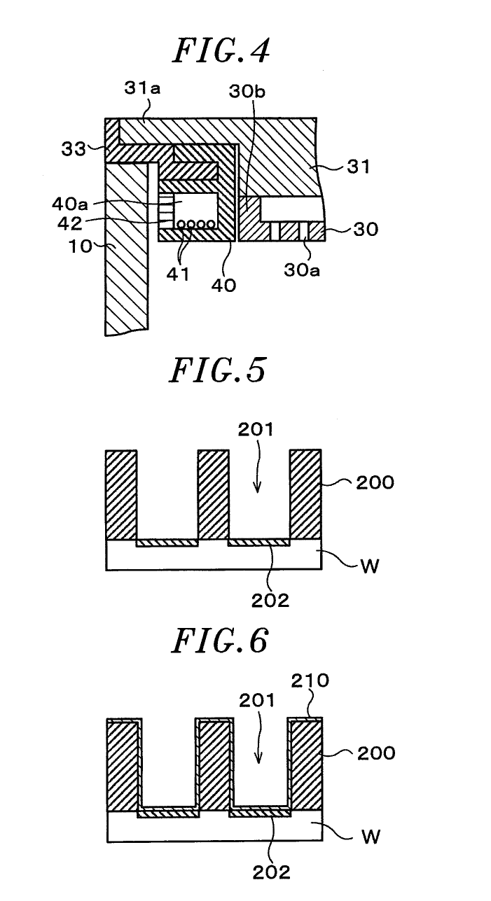

As shown in FIG. 2, for example, in an upper portion of the insulating member 40, a downwardly recessed portion 40a is formed along the entire circumference of the insulating member 40. As shown in FIG. 3, for example, a heating unit 41 is provided along the entire circumference of the recessed portion 40a. Accordingly, the insulating member 40 can be heated to a predetermined temperature. An upper part of the recessed portion 40a is covered by a ring-shaped lid member 42. The heating unit 41 is accommodated in a space surrounded by the insulating member 40 and the lid member 42. As for the heating unit 41, it is possible to use, e.g., an electric heater or the like. In FIG. 3, there is illustrated, as the heating unit 41, a structure in which a single electric heater is disposed in a spiral shape in the recess 40a, for example. However, the arrangement type and the number of the heating unit 41 are not limited to those described in the present embodiment. The heating unit 41 having the spiral shape as shown in FIG. 3 may be adhered to the recess 40a directly or via a metal plate provided on the surface thereof). Or, the heating unit 41 may have a plate shape. A plurality of heating units 41 may be arranged in a concentric circular shape as long as the insulating member 40 can be heated to a predetermined temperature. The arrangement type and the number of the heating units 41 may vary. The recessed portion 40a is not necessarily formed in the upper portion of the insulating member 40 as long as the heating unit 41 can be properly disposed. As shown in FIG. 4, for example, the recessed portion 40a may be recessed horizontally from the outer peripheral surface toward the center of the insulating member 40.

A gas supply line 50 is connected to the gas diffusion space 32 while penetrating through the lid 31. As shown in FIG. 1, a processing gas supply source 51 is connected to the gas supply line 50. A processing gas is supplied from the processing gas supply source 51 to the gas diffusion space 32 through the gas supply line 50. The processing gas supplied into the gas diffusion space 32 is introduced into the processing chamber 10 through the gas supply openings 30a. In that case, the upper electrode 30 serves as a shower plate for introducing the processing gas into the processing chamber 10.

In the present embodiment, the processing gas supply source 51 includes: a source gas supply unit 52 for supplying TiCl₄ gas as a source gas for forming a Ti film; a reduction gas supply unit 53 for supplying a reduction gas, e.g., H₂ (hydrogen) gas; and a rare gas supply unit 54 for supplying a rare gas for plasma generation. Ar (argon) gas is used, for example, as the rare gas supplied from the rare gas supply unit 54. The processing gas supply source 51 further includes valves 55 and flow rate controllers 56 provided between the respective gas supply units 52 to 54 and the gas diffusion space 32. Flow rates of the respective gases supplied to the gas diffusion space 32 are controlled by the flow rate controllers 56.

A high frequency power supply 60 that supplies a high frequency power to the upper electrode 30 through the lid 31 to generate a plasma is electrically connected to the lid 31 via a matching unit 61. The high frequency power supply 60 is configured to output a high frequency power having a frequency of 100 kHz to 100 MHz, e.g., 450 kHz in the present embodiment. The matching unit 61 for matching a load impedance with an internal impedance of the high frequency power supply 60 functions such that the load impedance and the internal impedance of the high frequency power supply 60 apparently match when a plasma is generated in the processing chamber 10.

A gas exhaust unit 70 for exhausting the inside of the processing chamber 10 is connected to the bottom surface of the processing chamber 10 through a gas exhaust line 71. A control valve 72 for controlling an exhaust amount of the gas exhaust unit 70 is provided at the gas exhaust line 71. By driving the gas exhaust unit 70, the atmosphere in the processing chamber 10 is exhausted through the gas exhaust line 71. Accordingly, a pressure in the processing chamber 10 can be decreased to a predetermined vacuum level.

The substrate processing apparatus 1 includes a control unit 100. The control unit 100 is, e.g., a computer, and includes a program storage unit (not shown). The program storage unit stores a program for operating the substrate processing apparatus 1 by controlling the respective components such as the heating unit 41, the flow rate controllers 56, the high frequency power supply 60, the matching unit 61, the gas exhaust unit 70, the control valve 72 and the like.

The program is stored in a computer readable storage medium such as a hard disk (HD), a flexible disk (FD), a compact disk (CD), a magneto-optical disk (MO), a memory card or the like. The program may be read out from the storage medium and installed in the control unit 100.

The substrate processing apparatus 1 of the present embodiment is configured as described above. The following is description on a process of forming a Ti film on the wafer W in the substrate processing apparatus 1 of the present embodiment.

In order to perform the film forming process, the wafer W is first loaded into the processing chamber 11 and mounted on the mounting table 11. As shown in FIG. 5, for example, an insulating layer 200 having a predetermined thickness is formed on the surface of the wafer W and trenches 201 are formed at a portion of the insulating layer 200. The trenches 201, i.e., so-called contact holes, are formed above the conductive layer 202 corresponding to a source or a drain formed on the wafer W.

When the wafer W is held on the mounting table 11, the inside of the processing chamber 10 is exhausted by the gas exhaust unit 70 and TiCl₄ gas, H₂ gas and Ar gas are supplied at respective predetermined flow rates from the processing gas supply source 51 into the processing chamber 10. The flow rate controllers 56 are controlled such that TiCl₄ gas, H₂ gas and Ar gas are supplied at the flow rates of about 5 sccm to 50 sccm, about 5 sccm to 10000 sccm, and about 100 sccm to 5000 sccm, respectively. In the present embodiment, TiCl₄ gas, H₂ gas and Ar gas are supplied at the flow rates of about 6.7 sccm, 4000 sccm and 1600 sccm, respectively. The opening degree of the control valve 72 is controlled such that the pressure in the processing chamber 10 is about 65 Pa to 1330 Pa, e.g., about 666 Pa in the present embodiment.

The upper electrode 30, the wafer W on the mounting table 11, and the insulating member 40 are heated to and maintained at about 400° C. or above by the electric heaters 20 and 34 and the heating unit 41. A description on the determination of the heating temperature will be provided later. Next, a high frequency power is consecutively applied to the upper electrode 30 by the high frequency power supply 60. As a consequence, the gases supplied into the processing chamber 10 are turned into a plasma containing ions or radicals of TiClₓ, Ti, Cl, H, Ar between the upper electrode 30 and the mounting table 11 serving as the lower electrode.

TiClₓ as a source gas, which is decomposed by the plasma, is reduced by H ions or H radicals as a reduction gas on the surface of the wafer W. As a consequence, a Ti film 210 is formed on the wafer W as shown in FIG. 6. A reaction by-product caused by the processing gas is adhered to the inner surface of the processing chamber 10, which leads to formation of a film. Since the surfaces of the mounting table 11, the upper electrode 30 and the insulating member 40 are heated to about 400r or above, a film quality of the adhered film is improved and, thus, peeling and crack of the adhered film can be suppressed. As a result, the amount of particles adhered to the wafer W is reduced and the processing can be carried out at a high yield rate. The description on the improvement of the film quality of the adhered film will be provided later.

When the processing of the wafer W is completed, the wafer W is unloaded from the processing chamber 10. Then, a new wafer W is loaded into the processing chamber 10. A series of the above processes of the wafer W is repeated.

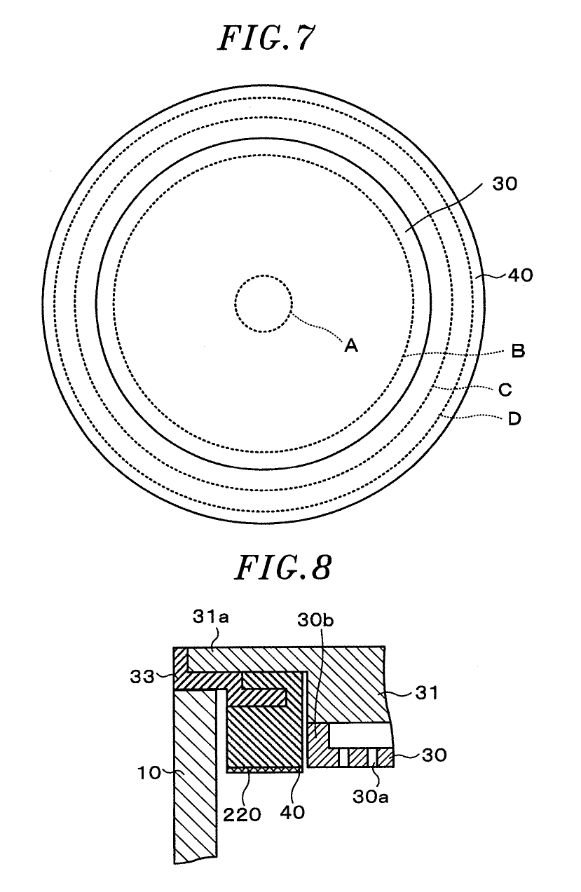

The following is the description on the improvement of the film quality of the adhered film. As described above, the Ti film is formed by the reaction between the source gas and the reduction gas on the surface of the wafer W. Since, however, it is difficult to reduce all of Cl, Cl is contained as an impurity in the Ti film. The present inventors have found that the film quality is decreased as the concentration of Cl in the Ti film is increased and the decrease in the film quality leads to peeling or crack of the film. The present inventors have considered that the peeling or the crack of the film results in generation of particles and the generation of particles can be suppressed by reducing the peeling or the crack of the adhered film by improving the film quality of the adhered film. The present inventors have studied the film quality of the film adhered to the inner surface of the processing chamber 10 in the conventional substrate processing apparatus in which the heating unit 41 is not provided at the insulating member 40. The film quality was examined by measuring the number of particles adhered to surfaces of respective portions of the processing chamber 10 by a simple particle monitor of suction type, for example. It is considered that, at a portion where a large number of particles was generated, the film quality was decreased to cause peeling or crack of the film, which led to generation of particles and adhesion of the particles to the surface. The number of particles was measured at a central portion of the bottom surface of the upper electrode 30 (near a circle A in FIG. 7), an outer peripheral portion of the bottom surface of the upper electrode 30 (near a circle B in FIG. 7), an inner peripheral portion of the bottom surface of the insulating member 40 (near a circle C in FIG. 7) and an outer peripheral portion of the bottom surface of the insulating member 40 (near a circle D in FIG. 7). At this time, particles having a particle diameter of about 0.3 μm or above were measured. The number of particles is not measured at, e.g., the sidewall of the processing chamber 10 for the following reasons. The wafer W is separated from the sidewall of the processing chamber 10 by a sufficient distance. Further, if the film is peeled or cracked at the sidewall of the processing chamber 10, particles generated therefrom do not scatter toward the wafer W, because an exhaust flow formed by the gas exhaust unit 70 flows downward in the processing chamber 10.

According to the measurement result, the number of particles measured at both of the central portion and the outer peripheral portion of the upper electrode 30 was about 10 to 50. The number of particles measured at the inner peripheral portion of the insulating member 40 was about 200 to 1100. The number of particles measured at the outer peripheral portion of the insulating member 40 was about 700 to 2800. From this result, it is expected that the film adhered to the conventional insulating member 40 having no heating unit 41 has a poor film quality compared to the film adhered to the upper electrode 30 and, thus, such a film is easily peeled or cracked. This is because the surface temperature of the conventional insulating member 40 is relatively lower than that of the upper electrode 30 heated by the electric heater 34 and, thus, the reduction reaction on the surface of the insulating member 40 is insufficient compared to that on the upper electrode 30. As a result, the film containing a large amount of Cl as an impurity, i.e., the film having a poor film quality, is adhered on the surface of the insulating member 40.

Therefore, the present inventors have performed an additional test to obtain relation between a film quality and a surface temperature of a film adhesion object. In this test, the concentration of Cl in the film adhered on the upper electrode 30 was measured at the central portion and the outer peripheral portion of the upper electrode 30 while varying the temperature of the upper electrode 30 to, e.g., about 370° C., 460° C., and 500° C. As a result, the concentration of Cl in the adhered film in the case of setting the temperature of the upper electrode 30 to about 370° C. was about 1% to 9% at the central portion and about 1% to 18% at the outer peripheral portion. Further, the concentration of Cl in the adhered. film in the case of setting the temperature of the upper electrode 30 to about 460° C. was about 1% at the central portion and about 1% to 4% at the outer peripheral portion. Moreover, the concentration of Cl in the adhered film in the case of setting the temperature of the upper electrode 30 to about 500° C. was about 0.5% to 0.8% at the central portion and about 0.7% to 1% at the outer peripheral portion. From the above, it is clear that the film haying lower concentration of Cl, i.e., the film having a smaller amount of impurities, can be formed as the temperature of the upper electrode 30 is increased. Thus, as the surface temperature of the film adhesion object is increased, the film quality of the adhered film is improved. As a result, it is possible to suppress generation of particles caused by peeling or crack of the adhered film.

The following is description on setting of the surface temperature of the film adhesion object, e.g., the upper electrode 30 and the insulating member 40.

As described above, there are two reasons that the film quality needs to be improved as the surface temperature of the film adhesion object is increased. First, as the temperature is increased, the reduction by the reduction gas is facilitated and, thus, Cl as an impurity is more easily volatilized as HCl during the reduction reaction between TiCl, and H radicals or H ions in the film forming process. Second, as the surface temperature of the film adhesion object is increased, TiCl, is more easily volatilized from the surface. Thus, TiCl, as a gas to be reduced is hardly condensed or adhered.

In the present embodiment, for example, a partial pressure of TiCl₄ gas in the processing chamber 10 is about 1.33 Pa. and a saturation vapor pressure of TiCl₃ gas at about 400° C., is about 1.33 Pa. Accordingly, it is preferable to maintain the surface temperature of the film adhesion object at about 400° C. or above. This is clear from the result that the concentration of Cl in the adhered film is lower when the surface temperature of the upper electrode 30 is set. to about 460° C. 13 and 500° C. than when it is set to about 370° C. From the above, it is preferable to set the surface temperature of the film adhesion object to a temperature at which a partial pressure of the main source gas or at least one of reaction intermediates of the main source gas is equal to a saturation vapor pressure of the source gas or to a higher temperature.

In other words, it is preferable to set the surface temperature of the film adhesion object to a level higher than or equal to a saturation temperature of the source gas or at least one of the reaction intermediates thereof at the pressure in the processing chamber. When the source gas is, e.g., TiCl₄, the reaction intermediates are TiCl₃, TiCl₂, TiCl, Ti, Cl, Cl₂. In the substrate processing apparatus 1 of the present embodiment, the heating temperatures of the upper electrode and the insulating member 40 are preferably higher than a saturation vapor temperature of TiCl₃, i.e., about 400° C., which is a relatively lower saturation vapor temperature among saturation vapor temperatures of the reaction intermediates of TiCl₄ as a source gas at the pressure in the processing chamber 10. An upper limit of the heating temperature is preferably lower than or equal to, e.g., about 700° C. In the present embodiment, as described above, the heating temperature is set to about 450° C. which is higher than the saturation vapor temperature. Further, the saturation vapor temperature at the partial pressure of TiCl₂ in the processing chamber is about 535° C.

In the above-described embodiment, the concentration of Cl can be decreased by promoting the reduction reaction on the surface of the insulating member 40 by heating the insulating member 40 using the heating unit 41. Since the heating temperature of the insulating member 40 is higher than the saturation vapor temperature at the partial pressure of the source gas in the processing chamber 10, the concentration of Cl, from the source gas, adhered to the surface of the insulating member 40 can be decreased. Accordingly, the film quality of the adhered film can be improved. As a result, peeling and crack of the film adhered to the insulating member 40 are reduced and the generation of particles in the processing chamber 10 is suppressed.

In the above-described embodiment, the heating unit 41 is provided along the entire circumference of the insulating member 40. However, the heating unit 41 or the recess 40a may not be provided along the entire circumference of the insulating member 40 as long as the entire bottom surface of the insulating member 40 can be properly heated. The shape or the arrangement thereof may vary.

In the above-described embodiment, the electric heater is used as the heating unit 41 for heating the insulating member 40. However, the type of the heating unit 41 is not limited to that of the present embodiment and may vary as long as the insulating member can be properly heated. For example, as shown in FIG. 8, a coating film 220, which absorbs infrared rays having a predetermined wavelength, may be coated on the surface of the insulating member 40 and be heated by absorbing infrared rays emitted from the upper electrode 30 and the mounting table 11 in the processing chamber 10. In that case, even though the object on which the film is adhered is the coating film 220 itself, the film quality of the film adhered to the coating film 220 can be improved by heating the coating film 220 as in the case of heating the insulating member 40 by the heating unit 41, e.g., the electric heater. In the present embodiment, the coating film 220 serves as the heating unit 41. Further, although the coating film 220 is formed only on the bottom surface of the insulating member 40 as shown in FIG. 8, the coating film 220 may be formed on the entire surface of the insulating member 40. On the assumption that the particles are mainly caused by the film adhered to the surface of the insulating member 40 which faces the wafer W, it is effective to form the coating film 220 on the surface facing the wafer W, i.e., the bottom surface of the insulating member 40.

In case of using TiCl₄ gas as a source gas, it is preferable to use infrared rays having a temperature of about 400° C. to 500° C. and a Ni (nickel) alloy thermally sprayed film or the like is preferably used as the coating film 220. Since Ni has high thermal conductivity and high resistance to a plasma, the coating 220 itself does not generate particles. Carbon or quartz doped with a metal may be used other than Ni.

The present inventors have found that when the wafer W was processed by using the substrate processing apparatus 1 including the insulating member 40 having on a surface thereof the coating film 220, the number of particles adhered to the surface of the wafer W and having a particle size of, e.g., about 0.045 μm or above, was reduced to about ¼ of the number of particles adhered to the wafer W processed by using the conventional insulating member that does not have the coating film 220 and the heating unit 41. Accordingly, even in the case of using the coating film 220 as the heating unit, the film quality of the adhered film can be improved and, further, the generation of particles can be suppressed.

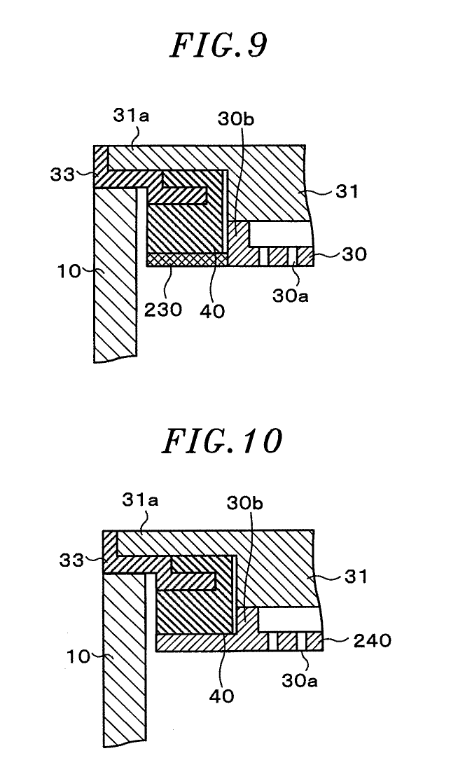

The coating film 220 is not necessarily formed by spraying. A ring-shaped metal plate 230, if it can be heated to a desired temperature by absorbing infrared rays in the processing chamber 10, may be provided, instead of the coating film 220, to cover the entire bottom surface of the insulating member 40 as shown in FIG. 9. In this case, the bottom surface of the metal plate 230 needs to be flush with the bottom surface of the upper electrode 30 in order to prevent uneven distribution of the plasma in the processing chamber 10. As in the case of the coating film 230, the metal film 230 may be made of a Ni alloy or the like.

In the case of using the metal plate 230, the metal plate 230 is not necessarily made of a material that absorbs infrared rays. The metal plate 230 may be made of, e.g., a metal having high thermal conductivity. As shown in FIG. 9, the metal plate 230 may be disposed in contact with the upper electrode 30 and heated by heat transferred from the upper electrode 30. When the upper electrode 30 and the metal plate 230 are disposed in contact with each other, it is possible to prevent adhesion of a film to the gap between the insulating member 40 and the upper electrode 30. As a result, the particles can be further reduced.

Further, in the case of using the metal plate 230, if a distance between an outer edge portion of the metal plate 230 and the inner surface of the processing chamber 10 is small, a plasma may be generated between the metal plate 230 and the processing chamber 10. Therefore, it is preferable to ensure a predetermined distance between the metal plate 230 and the processing chamber 10.

It is also possible to use another upper electrode 240 having a bottom surface extending to the outer edge portion of the insulating member 40 as shown in FIG. 10, for example, in view of covering the bottom surface of the insulating member 40 with a member that absorbs infrared rays.

However, in case of using another upper electrode 240, the electric field in the processing chamber 10 is different from that obtained in the case of using the upper electrode due to the increase in the diameter of the upper electrode 240. On the other hand, in the case of using the coating film 220, it does not serve as the upper electrode, because it is not in direct contact with the upper electrode 30 and has an extremely small thickness and low conductivity. Accordingly, it is preferable to use, as the heating unit, the coating film 220 or the metal plate 230 having a thickness or a diameter enough to avoid the effect on the electric field in the processing chamber 10.

Further, the insulating member 40 itself may be made of a material that absorbs infrared rays, instead of providing a member that absorbs infrared rays in the processing chamber 10 at the bottom surface of the insulating member 40. In this case, the insulating member 40 may be made of Ni alloy, carbon, quartz doped with a metal or the like.

While the disclosure has been shown and described with respect to the embodiments, it will be understood by those skilled in the art that various changes and modifications may be made without departing from the scope of the disclosure as defined in the following claims. Although the above embodiment has described the case of performing a film forming process on a wafer by using a plasma, the present invention may also be applied to a substrate processing apparatus for performing an etching process by using a plasma or the like.

What is claimed is:

1. A substrate processing apparatus for processing a substrate by using a plasma, comprising:
a processing chamber configured to airtightly accommodate a substrate;
a lower electrode serving as a mounting table configured to mount thereon the substrate in the processing chamber;
an upper electrode, serving as a shower plate having a plurality of gas supply openings, provided opposite to the substrate to be mounted on the mounting table;
an insulating member disposed to surround an outer peripheral portion of the upper electrode;
a processing gas supply source configured to supply a processing gas into the processing chamber through the shower plate; and
a heating unit provided at the insulating member to heat the insulating member.

2. The substrate processing apparatus of claim 1, wherein the heating unit is a heater provided inside the insulating member.

3. The substrate processing apparatus of claim 2, wherein a ring-shaped recessed portion is formed in the insulating member to surround the upper electrode, and
wherein the heater is provided in the recessed portion.

4. The substrate processing apparatus of claim 1, wherein the heating unit is a ring-shaped member disposed to cover a bottom surface of the insulating member facing toward the mounting table, and
wherein the ring-shaped member includes a nickel alloy.

5. The substrate processing apparatus of claim 1, wherein the heating unit is a nickel alloy film attached to a bottom surface of the insulating member facing toward the mounting table.

6. The substrate processing apparatus of claim 1, wherein the insulating member includes a material that absorbs infrared rays having a predetermined wavelength and serves as the heating unit by absorbing the infrared rays generated in the processing chamber.

7. The substrate processing apparatus of claim 1, wherein the processing gas contains TiCl₄ gas.

8. The substrate processing apparatus of claim 1, further comprising a control unit configured to control the heating unit to heat the insulating member to a temperature higher than or equal to a saturation vapor temperature of at least one of reaction intermediates of the processing gas under a pressure in the processing chamber.

9. A plasma processing method using the apparatus of claim 1, comprising:
supplying the processing gas into the processing chamber; and
generating the plasma from the processing gas to process the substrate,
wherein one or more reaction intermediates of the processing gas is generated in said generating the plasma, and
wherein the insulating member is heated to a temperature higher than or equal to a saturation vapor temperature of at least one of reaction intermediates of the processing gas during said generating the plasma.
